(19) United States
(12) Patent Application Publication
(10) Pub. No.: US 2026/0262274 A1
(43) Pub. Date: Sep. 3, 2026

(54) LOCALLY DISPLACED ACTIVE AREA IN STACKED TOP TRANSISTOR

(71) Applicant: International Business Machines Corporation, Armonk, NY (US)

(72) Inventors: James Patrick Mazza, Saratoga Springs, NY (US); Ruilong Xie, Niskayuna, NY (US); Albert Manhee Chu, Nashua, NH (US); Brent Alan Anderson, Jericho, VT (US); Nicholas Anthony Lanzillo, Wynantskill, NY (US); Tenko Yamashita, Schenectady, NY (US); Junli Wang, Slingerlands, NY (US); Shay Reboh, Guilderland, NY (US)

(21) Appl. No.: 19/066,622

(22) Filed: Feb. 28, 2025

(51) Int. Cl. H10D 64/23; H10D 30/00; H10D 30/01; H10D 30/43; H10D 84/01; H10D 84/85

(52) U.S. Cl. CPC H10D 64/251; H10D 30/014; H10D 30/0191; H10D 30/43; H10D 30/502; H10D 84/0186; H10D 84/851

(57) ABSTRACT

The present disclosure describes a semiconductor IC device that includes a locally displaced to transistor active area. The locally displaced top active region may be associated with a top transistor that is stacked over the bottom transistor. The locally displaced top active region is offset or shifted with respect to the bottom active region and includes a displaced portion or region thereof that is offset or shifted to a lesser extent. For example, the top transistor active area may include a first portion that is laterally offset relative to the bottom active region by a first dimension and a locally displaced portion that is laterally offset relative to the bottom active region by a second dimension that is less than the first dimension. The displaced portion may allow adequate space for placement of a through interconnect without otherwise increasing an associated transistor horizontal cell dimension.

### BACKGROUND

A stacked transistor may include a top transistor stacked upon a bottom transistor. Routing though a cell that includes the top transistor and the bottom transistor and routing to and from regions within the top transistor and within the bottom transistor is difficult. A current solution to routing through the cell is to undesirably increase lateral dimension(s) of the cell to accommodate the through cell connector.

### SUMMARY

In an embodiment of the disclosure, a semiconductor integrated circuit (IC) device is presented. The semiconductor IC device includes a bottom active region and a top active region. The top active region includes a first portion that is laterally offset relative to the bottom active region by a first dimension and a locally displaced portion that is laterally offset relative to the bottom active region by a second dimension less than the first dimension.

In another embodiment of the disclosure, a semiconductor integrated circuit (IC) device is presented. The semiconductor IC device includes a first cell comprising a first dimension from an edge of a top active region to a distal edge of a bottom active region and a second cell comprising a second dimension from the edge of the top active region to the distal edge of the bottom active region, wherein the second dimension is less than the first dimension.

In another embodiment of the disclosure, a semiconductor integrated circuit (IC) device fabrication method is presented. The method includes forming a bottom transistor that includes a bottom active region and forming a locally displaced top active region that comprises a first portion that is laterally offset relative to the bottom active region by a first dimension and a locally displaced portion that is laterally offset relative to the bottom active region by a second dimension less than the first dimension.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a cross-section view of a semiconductor IC device that includes a locally displaced top transistor active area, according to one or more embodiments of the disclosure.

FIG. 2 through FIG. 10 depict various fabrication structure cross-section views of an illustrative semiconductor IC device that includes a locally displaced top transistor active area, according to one or more embodiments of the disclosure.

FIG. 11 depicts a partial top down view of an illustrative semiconductor IC device that includes a locally displaced top transistor active area, according to one or more embodiments of the disclosure.

FIG. 12 depicts a partial top down view of an illustrative semiconductor IC device that includes a locally displaced top transistor active area, according to one or more embodiments of the disclosure.

FIG. 13 depicts a method of fabricating a semiconductor IC device that includes a locally displaced top transistor active area, according to one or more embodiments of the disclosure.

### DETAILED DESCRIPTION

The present disclosure relates to fabrication methods and resulting semiconductor integrated circuit (IC) devices that include a stacked transistor with an etch stop bonding structure. The etch stop bonding structure may provide robust or adequate etch stop protection, at least associated with the pre-clean etch and subsequent fabrication of an associated source/drain region of a top transistor. The etch stop etch stop bonding structure may protect against or prevent the associated fabricated source/drain region electrically shorting with an adjacent gate structure.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating semiconductor IC device, such as a processor, FPGA, memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “top,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling gate lengths. Integration of multiple transistors, such as a bottom transistor and a top transistor, into a stacked configuration may allow for continued device scaling. However, there are many fabrication challenges in order to form stacked transistors at scale.

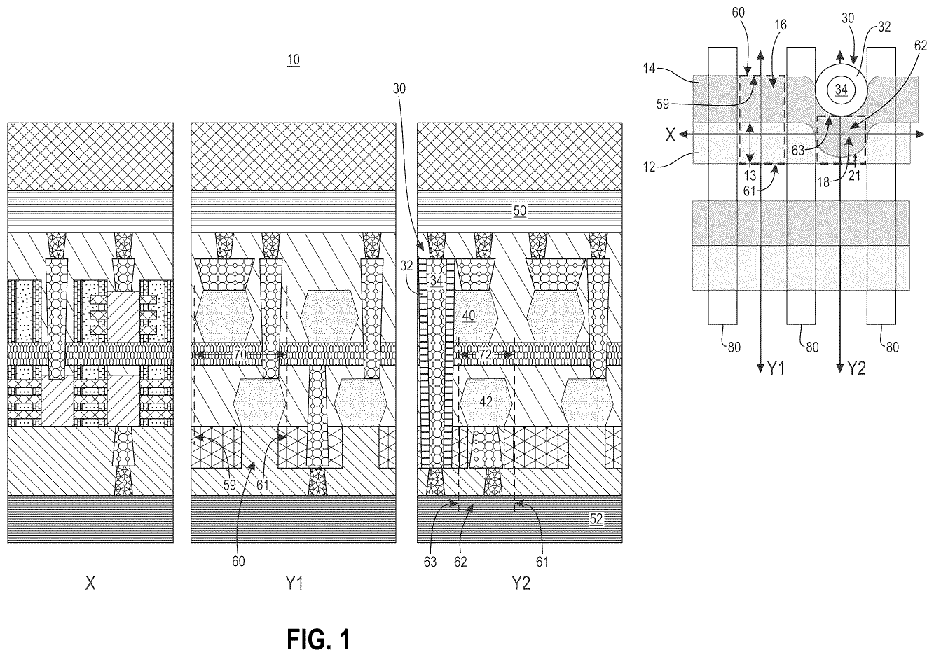

Please refer to FIG. 1, that depicts a cross-section view of a semiconductor IC device 10. In an embodiment, semiconductor IC device 10 includes a bottom active region 12 and a top active region 14. Top active region 14 includes a first portion 16 that is laterally offset relative to the bottom active region 12 by a first dimension 13 and a locally displaced portion 18 that is laterally offset relative to the bottom active region 12 by a second dimension 21 that is less than the first dimension 13.

In an example, semiconductor IC device 10 further includes a through interconnect 30 adjacent to the locally displaced portion 18. The through interconnect 30 may include a perimeter dielectric liner 32 and an internal conductive pillar 34. In an example, the semiconductor IC device 10 further includes a top source/drain (S/D) region 40 within the locally displaced portion 18 of the top active region 14. In an example, the top S/D region 40 is connected to a frontside back end of line (BEOL) network 50. In an example, the top S/D region 40 is directly connected to the perimeter dielectric liner 32 of the through interconnect 30.

In an example, semiconductor IC device 10 further includes a bottom S/D region 42 within the bottom active region 12 below the top S/D region 40. In an example, the bottom S/D region 42 is connected to a backside BEOL network 52. In an example, the internal conductive pillar 34 is connected to the frontside BEOL network 50 and to the backside BEOL network 52.

In another embodiment, another semiconductor IC device 10 is presented. The semiconductor IC device 10 includes a first cell 60 that includes a dimension 70 from an edge 59 of the top active region 14 to a distal edge 61 of the bottom active region 12. The semiconductor IC device 10 includes a second cell 62 that includes a second dimension 72 from the edge 63 of the top active region 14 to the distal edge 61 of the bottom active region 12. The second dimension is less than the first dimension and the size of the cells may be substantially the same.

In an example, the top active region 14 includes the first portion 16 in the first cell 60 and the locally displaced portion 18 within the second cell 62. In an example, the displaced portion 18 of the top active region 14 is curved relative to the first portion 16 of the top active region 14.

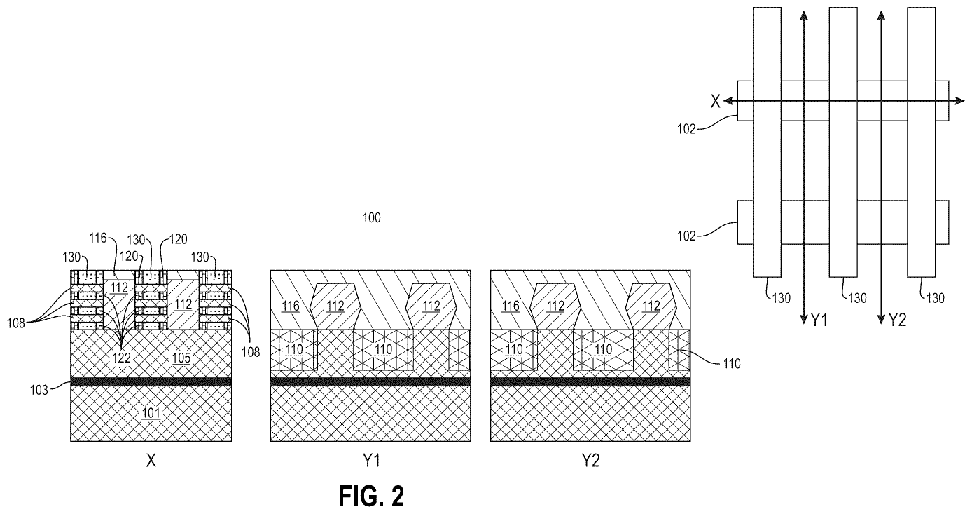

FIG. 1 depicts a partial top-down structure view of a semiconductor IC device 10 and establishes an illustrative cross-sectional planes Y1, Y2, and X for the views of the semiconductor IC device structure 10. The X cross-sectional plane is through the bottom active region 12, through the locally displaced portion 18 of the top active region 14, and across gate structures 80. The Y1 cross-sectional plane is through the bottom active region 12, through the first portion 16 of the top active region 14, and between gate structures 80. The Y2 cross-sectional plane is through the bottom active region 12, through the locally displaced portion 18 of the top active region 14, and between gate structures 80. For clarity, the partial top-down structure views of the semiconductor IC device(s) that establish the Y1, Y2, and X cross-sectional planes are repeated in FIG. 2 through FIG. 12, the description(s) of which are not repeated herein.

FIG. 2 depicts an initial fabrication structure cross-section view of an illustrative semiconductor IC device 100, according to one or more embodiments of the disclosure. For clarity, the fabrication of the semiconductor IC device 100 at the present stage may utilize processes that may now be known or that may be developed in the future. For illustration purposes, a particular fabrication process to form semiconductor IC device 100 at the present stage is presented below. This illustrative methodology may be one of many that may achieve or result in the initial semiconductor IC device 100, as depicted. When components referenced in the illustrative methodology below are depicted in FIG. 2, such associated component numeral is expressly utilized. Otherwise, when components are referenced in the illustrative methodology that are not depicted in FIG. 2, a component numeral is not denoted.

The illustrative semiconductor IC device 100 may be formed by initially providing or forming a substrate structure. The substrate structure may be a bulk-semiconductor substrate. In one example, the bulk-semiconductor substrate may be a silicon-containing material. In the depicted implementation, the substrate structure includes an upper substrate 105, a lower substrate 101, and an etch stop layer 103 between the upper substrate 105 and the lower substrate 101. The upper substrate 105 and the lower substrate 101 may be comprised of any suitable silicon-containing material(s), and the etch stop layer 103 may be a dielectric material with etch selectivity to one or both upper substrate 105 and/or the lower substrate 101. In one example, the etch stop layer 103 may be an oxide and the substrate structure may be referred to as a buried oxide (BOX) substrate. In a particular example, the lower substrate 101 may be composed of silicon. The etch stop layer 103 may be composed of Silicon Germanium (SiGe) and may be epitaxially grown from the top surface of lower substrate 101 and the upper substrate 105 may be composed of Si and may be epitaxially grown from the top surface of etch stop layer 103.

The illustrative semiconductor IC device 100 may be formed by forming nanolayers over the substrate structure by forming a bottommost sacrificial nanolayer (not shown) and by forming a series of alternating sacrificial nanolayers (not shown) and active nanolayers 108 thereupon. In an implementation, the alternating active sacrificial nanolayer and active nanolayer 108 may be formed by epitaxially growing each layer until the desired number and desired thicknesses of the layers are achieved. Any number of alternating nanolayers can be provided. Epitaxial materials can be grown from gaseous or liquid precursors. For example, epitaxial materials can be grown using vapor-phase epitaxy (VPE), molecular-beam epitaxy (MBE), liquid-phase epitaxy (LPE), or other suitable processes.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

Although it is specifically contemplated that the bottommost sacrificial nanolayer and the sacrificial nanolayers can be formed from SiGe and that the active nanolayers 108 can be formed from Si, it should be understood that any appropriate materials can be used instead, as long as the semiconductor materials have etch selectivity with respect to one or more of the others, as is consistent with the description of the fabrication stages herein.

Although it is specifically contemplated that the bottommost sacrificial nanolayer, the sacrificial nanolayers, and the active nanolayers 108 are formed by epitaxial growth, such nanolayers can be formed by any appropriate mechanism, such as chemical vapor deposition (CVD), physical vapor deposition (PVD), atomic layer deposition (ALD), or gas cluster ion beam (GCIB) deposition, or the like.

The nanolayers may be patterned into nanolayer rows 102 and shallow trench isolation (STI) regions (not shown) may be formed. To form the nanolayer rows 102, a mask layer may be formed on the topmost nanolayer. The mask layer may be comprised of any suitable mask material(s). Utilizing photolithography and etching techniques, the mask layer may be patterned and used to perform the nanolayer stack patterning process. In the nanolayer stack patterning process, any suitable material removal process (e.g., reactive ion etching or RIE) may be used to remove portions of the alternating nanolayers down to the level of the substrate structure, or the like. Following the nanolayer stack patterning process, the one or more nanolayer rows 102 are formed and the mask layer may be removed.

The removal of undesired portion(s) of the alternating nanolayers may further remove undesired portions of substrate structure that are adjacent to respective footprints of nanolayer rows 102 to form STI region openings. The etch may be timed or otherwise controlled to stop the removal of the substrate structure such that the depth or bottom of the one or more STI region openings has a predetermined or desired dimension. For example, the depth or bottom of the one or more STI region openings may be above the etch stop layer 103, as depicted. In some examples, the etch to form the nanolayer rows 102 may utilize the etch stop layer 103 to stop the etch and form the bottom well of the one or more STI region openings.

A STI region 110 may be formed upon and/or within the substrate structure within respective STI region openings. The STI regions 110 may be formed by depositing electrical dielectric material(s) within respective STI region opening(s) that are adjacent to the one or more nanolayer rows 102. A top surface of the one or more STI regions 110 may be initially coplanar with or below a top surface of the substrate structure. In some implementations, further fabrication operations may generally remove portions of the STI regions 110 (e.g., sacrificial gate removal, replacement gate fabrication pre-clean, etc.), such that the top surfaces of the STI regions 110 are below the top surface of the substrate structure.

The one or more STI regions 110 may have a volume and/or geometry that sufficiently electrically isolates components or features of neighboring bottom transistors, or the like, may sufficiently electrically isolate neighboring nanolayer rows 102.

In an example, the STI regions 110 may be formed by depositing a STI liner within the STI region openings. Subsequently, STI regions 110 may be further formed by depositing STI dielectric material upon the STI liner. A etch back, recess, or the like, may occur to remove undesired or over formed STI liner and/or STI dielectric material, such that the top surface of the STI regions 110 are coplanar with or below a bottom surface of the bottommost sacrificial nanolayer. STI liner may be composed of but not limited to a nitride, low-κ nitride (e.g., a nitride material with a lower dielectric constant relative to SiO₂), or the like. The STI dielectric material may be composed of but not limited to an oxide, low-κ oxide (e.g., an oxide material with a lower dielectric constant relative to SiO₂), or the like.

The illustrated semiconductor IC device 100 may be further fabricated by forming sacrificial gate structures (not shown). The one or more sacrificial gate structures may be formed by patterning a gate cap layer, sacrificial gate layer, and sacrificial gate liner that are formed upon the nanolayers and STI regions 110 by, for example, using lithography and etch processes to remove undesired portions and retain desired portion(s), respectively. The retained desired portion(s) of the gate cap layer, sacrificial gate layer, and sacrificial gate liner may form a sacrificial gate liner, a sacrificial gate, and a sacrificial gate cap, respectively, of each of the one or more sacrificial gate structures. One or more sacrificial gate structures can be formed on targeted regions or areas of semiconductor IC device 100 to define the length of one or more GAA FETs and to provide sacrificial material for yielding targeted GAA FET structure(s) in subsequent processing.

The semiconductor IC device 100 may be further fabricated by forming gate spacers 120 upon the sidewall(s) of the sacrificial gate structures, upon the STI regions 110, and around the one or more nanolayer rows 102. The semiconductor IC device 100 may be further fabricated by next forming source/drain (S/D) recesses within the one or more nanolayer rows 102 between gate spacers of neighboring sacrificial gate structures. In other words, a single nanolayer row 102 may be separated, by one or more S/D recesses, into multiple nanolayer stacks each located underneath at a portion of respective sacrificial gate structure and associated gate spacer 120. The undesired portions of sacrificial nanolayers, active nanolayers 108, and the like, may be removed by etching or other subtractive removal techniques. As the gate spacers 120 and the sacrificial gate structures may be utilized to protect the underlying portions of sacrificial nanolayers and active nanolayers 108, respective sidewalls of the nanolayer rows 102 may be substantially coplanar and substantially vertical with the outer sidewalls of the gate spacers 120 there above.

As used herein, “substantially vertical” sidewalls deviate from a direction normal to a major surface (e.g., top surface, etc.) of the substrate 105 by less than 5°, e.g., 0°, 1°, 2°, 3°, 4°, or 5°, including ranges between any of the foregoing values.

The illustrated semiconductor IC device 100 may be further fabricated by forming horizontal or lateral indents by laterally or horizontally removing respective portions of sacrificial nanolayers within the nanolayer stacks. The indents may be formed by a reactive ion etch (RIE) process, which can remove portions of the sacrificial nanolayers. The illustrated semiconductor IC device 100 may be further fabricated by forming a respective inner spacer 122 within each indent. The one or more inner spacers 122 can be formed by ALD or CVD or any other suitable deposition technique that deposits a dielectric material within the indent(s), thereby forming the inner spacer(s) 122. In some examples, the inner spacers 122 are composed of a low-κ dielectric material (a material with a lower dielectric constant relative to SiO₂), SiN, SiO, SiBCN, SiOCN, SiCO, etc. or any other suitable dielectric material. In certain implementations, after the formation of the inner spacers 122, an isotropic etch process is performed to create substantially vertical sidewalls of the inner spacer(s) that are coplanar with the substantially vertical sidewalls of the active nanolayers 108, of the gate spacers, and/or of the bottom isolation.

The illustrated semiconductor IC device 100 may be further fabricated by forming a respective S/D region 112. Each S/D region 112 may form either a source or a drain, respectively, of respective bottom transistors of the stacked transistor, and is connected to respective end surface of the active nanolayers 108 of a nanolayer stack. Each S/D region 112 is composed of a semiconductor material and a dopant. As used herein, a “source/drain” region can be a source region or a drain region depending on subsequent wiring and application of voltages during operation of the applicable transistor. The semiconductor material that provides each of the S/D regions 112 may be composed of one of the semiconductor materials mentioned above for the semiconductor structure. For example, the semiconductor material that provides the S/D region 112 can be compositionally the same, or compositionally different from each active nanolayer 108. The dopant that is present in the S/D region 112 can be either a p-type dopant or an n-type dopant. The term “p-type” refers to the addition of impurities to an intrinsic semiconductor that creates deficiencies of valence electrons, and “n-type” refers to the addition of impurities that contributes free electrons to an intrinsic semiconductor.

The one or more S/D regions 112 may be epitaxially grown or formed. In some examples, the S/D region 112 are formed by in-situ doped epitaxial growth or an ex-situ process may be employed to introduce dopants into the S/D regions 112. Other doping techniques can be used to incorporate dopants in the S/D regions 112.

In some examples, the epitaxial growth that forms the S/D region 112 occurs or is promoted from the top surface of upper substrate 105, from the end surfaces of the active nanolayers 108, or the like, while epitaxial growth may be limited or does not occur from neighboring STI regions 110.

The illustrated semiconductor IC device 100 may be further fabricated by next forming interlayer dielectric (ILD) 116. For example, a blanket ILD 116 may be deposited over the S/D region(s) 112, over the STI regions 110, over the sacrificial gate structures, and over the gate spacers, and the like.

The ILD 116 can be any suitable material, such as, for example, porous silicates, carbon doped oxides, silicon dioxides, silicon nitrides, silicon oxynitrides, OPL, or other dielectric materials. In an example, the ILD 116 may be formed to a thickness above the top surface of the sacrificial gate structures. Subsequently, a planarization process, such as a CMP, may be performed to remove excess ILD 116 material and to remove the sacrificial gate caps of the sacrificial gate structures, thereby exposing the sacrificial gate thereunder. The planarization may also partially remove some of the sacrificial gates or may at least expose the sacrificial gate of the sacrificial gate structures.

The illustrated semiconductor IC device 100 may be further fabricated by removing the sacrificial gate structures and releasing the active nanolayers 108 within the nanolayer stacks. The sacrificial nanolayers may be removed by a removal technique, such as one or more series of etches. For example, the etching can include a wet chemical etching process in which one or more chemical etchants are used to remove the sacrificial nanolayers.

The illustrated semiconductor IC device 100 may be further fabricated by forming a replacement gate structure 130 in place of the removed sacrificial gate structures around the active nanolayers 108, upon STI regions 110, etc. Replacement gate structures 130 may be formed by initially forming an interfacial layer on the gate spacers, on the active nanolayers 108, on the bottom isolation, on the inner spacers, etc. that are interior to and/or upon the respective surfaces interior to the opening created by the removal of the sacrificial gate structure and the releasing of the active nanolayers 108. The interfacial layer can be deposited by any suitable techniques, such as ALD, CVD, PVD, thermal oxidation, combinations thereof, or other suitable techniques.

Replacement gate structures 130 may be further formed by forming a high-κ layer to cover the exposed surfaces of the interfacial layer. The high-κ layer can be deposited by any suitable techniques, such as ALD, CVD, metal-organic CVD (MOCVD), PVD, thermal oxidation, combinations thereof, or other suitable techniques. A high-κ material is a material with a higher dielectric constant than that of SiO2. The replacement gate structures 130 may be further formed by depositing a work function (WF) gate upon the high-κ layer. The WF gate sets the threshold voltage (Vt) of the device. The high-κ layer may separate the WF gate from the nanolayer channel (e.g., active nanolayer 108). Other metals that may be desired to further fine tune the effective work function (eWF) and/or to achieve a desired resistance value associated with current flow through the gate in the direction parallel to the plane of the nanolayer channel.

The one or more replacement gate structures 130 may be further formed by depositing a conductive gate. In an example, when none of the previous replacement gate material(s) are utilized in the replacement gate structures 130, the conductive gate may be formed upon the same or similar surfaces as those upon which the interfacial layer, described above, may be formed. In other examples, when one or more of the interfacial layer, the high-κ layer, the WF gate, or the like, are utilized in the replacement gate structures, the conductive gate may be formed upon the most recent structural formation thereof. The conductive gate can be comprised of a conductor material and/or metal, such as but not limited to, e.g., tungsten, aluminum, ruthenium, rhodium, cobalt, copper, tantalum, titanium, or the like. After the replacement gate structure 130 formation, the top surface of the semiconductor IC device 100 may be planarized by a planarization technique such as a CMP, mechanical grinding process, or the like.

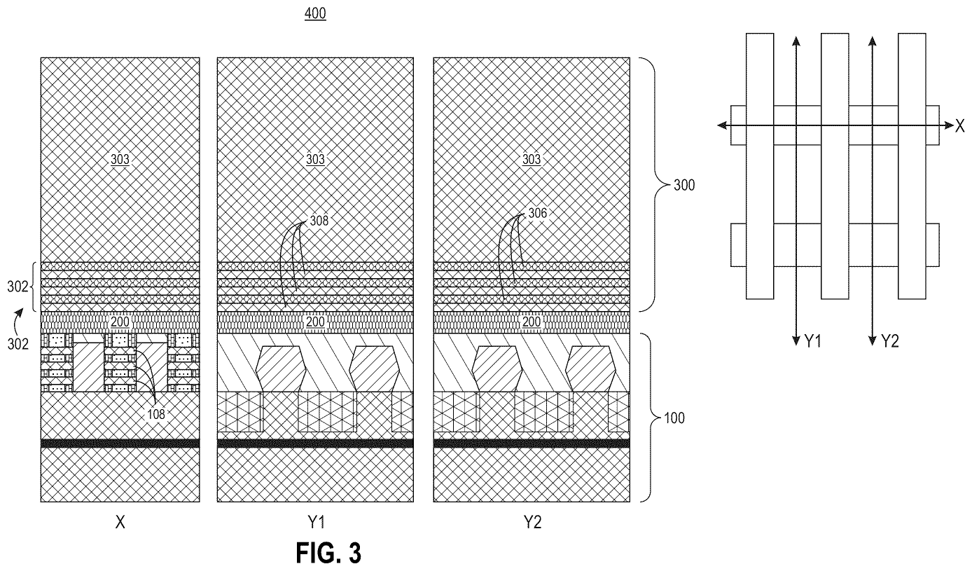

FIG. 3 depicts cross-sectional views of a semiconductor IC device 400 shown after representative fabrication operation(s), in accordance with one or more embodiments. In the depicted fabrication stage, a semiconductor IC device 300 that includes top transistor nanolayers 302 may be bonded to the semiconductor IC device 100.

For example, top transistor nanolayers 302, which includes a substrate 303 and alternating active nanolayers 308 and sacrificial nanolayers 306 may be bonded to the semiconductor IC device 100 by one or more bonding layer(s) 200. In such process, semiconductor IC device 300 that includes a second substrate 303 and the top transistor nanolayers 302 may be bonded to semiconductor IC device 100. One or more bonding layer(s) 200, which may be e.g., a bonding oxide, nitride, or other dielectric may be formed upon the semiconductor IC device 100 and/or the semiconductor IC device 300. Any known manner of forming the one or more bonding layer(s) 200 can be utilized. The one or more bonding layer(s) 200 can be formed using, for example, CVD, PECVD, ALD, flowable CVD, spin-on dielectrics, PVD, or the like.

In embodiments, the one or more bonding layer(s) 200 may be a blanket layer formed upon or otherwise associated with the top surface of the entire semiconductor IC device 100 and/or the entire semiconductor IC device 300.

In the example illustrated, there are a total of three sacrificial nanolayers 306 and three active nanolayers 308 that are alternately formed to create the top transistor nanolayers 302. However, it should be appreciated that any suitable number of alternating layers may be formed. Although it is specifically contemplated that the sacrificial nanolayers can be formed from SiGe and that the active nanolayers 308 can be formed from Si, it should be understood that any appropriate materials can be used instead, as long as the two semiconductor materials have etch selectivity with respect to one another.

In certain embodiments, the sacrificial nanolayers 306 have a vertical thickness ranging, for example, from approximately 3 nm to approximately 20 nm. In certain embodiments, the active nanolayers 308 have a vertical thickness ranging, for example, from approximately 3 nm to approximately 10 nm. Although the range of 3-20 nm is cited as an example range of thickness, other thickness of these layers may be used. In certain examples, certain of the sacrificial nanolayers or the active nanolayers 308 may have different thicknesses relative to one another. Therefore, multiple epitaxial growth processes can be performed to form the alternating top transistor nanolayers 302.

In certain embodiments, it may be desirable to have a vertical space between adjacent top transistor nanolayers 302 to reduce the parasitic capacitance and to improve circuit speed. For example, the VSP (the distance between adjacent active nanolayers 308) may range from 5 nm to 15 nm. However, the VSP should be of sufficient value to accommodate the replacement gate that will be formed in the spaces created by later removal of respective portions of the sacrificial nanolayers. In some cases, the vertical thickness of the active nanolayers 308 and/or spacing between the active nanolayers are the same or different relative to the associated dimensions of the active nanolayers 108.

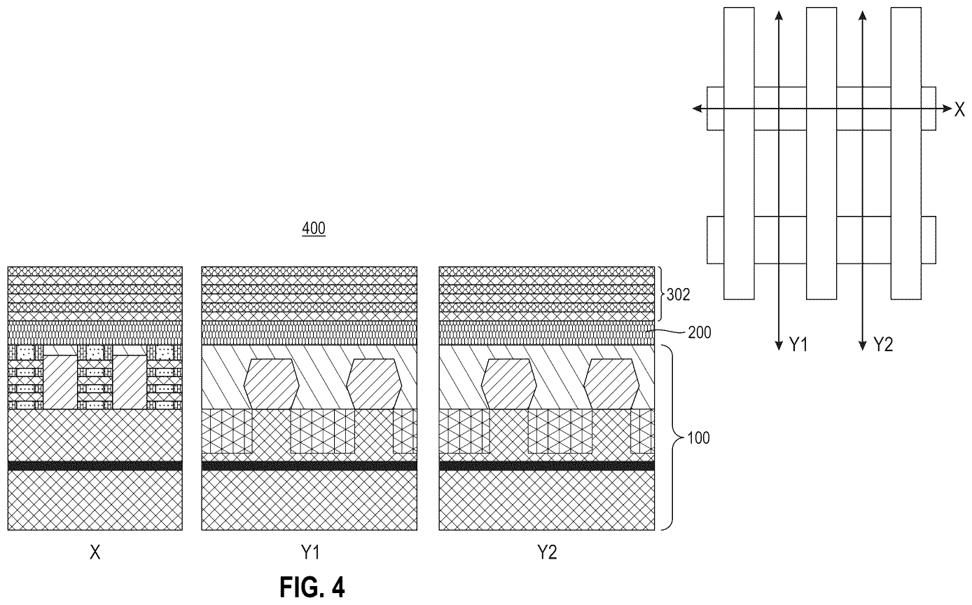

FIG. 4 depicts cross-sectional views of semiconductor IC device 400 shown after representative fabrication operation(s), in accordance with one or more embodiments. In the depicted stages, the substrate 303 may be removed, and the top transistor nanolayers 302 may be retained and otherwise associated with the semiconductor IC device 100 by the one or more bonding layer(s) 200. The substrate 303 may be removed by any known removal process, such as an etch, a CMP, or the like.

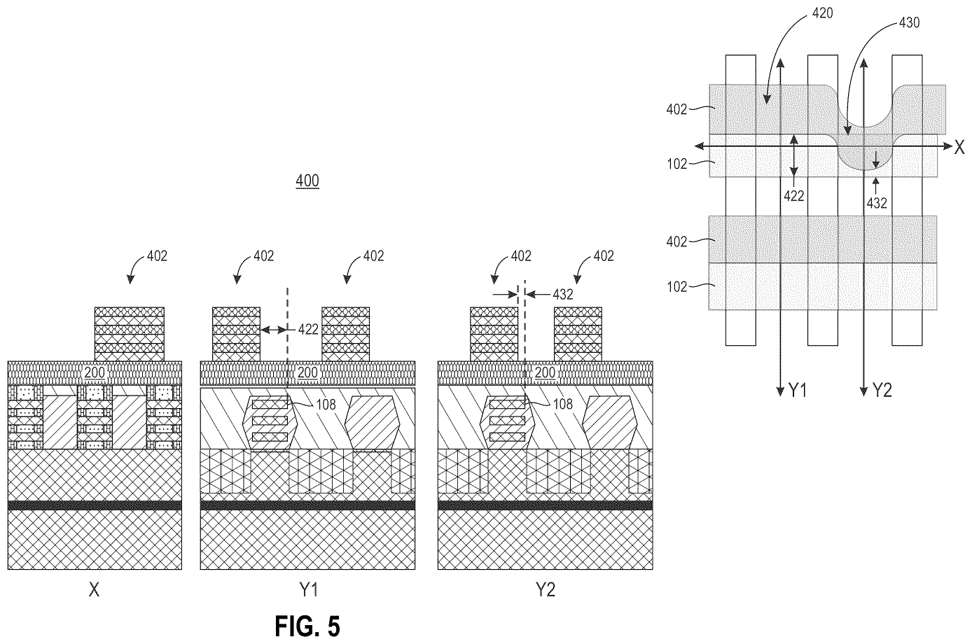

FIG. 5 depicts cross-sectional views of semiconductor IC device 400 shown after representative fabrication operation(s), in accordance with one or more embodiments. In the depicted stages, the top transistor nanolayers 302 may be patterned.

For example, the top transistor nanolayers 302 may be patterned into nanolayer rows 402. To form one or more nanolayer rows 402, a mask layer (not shown) may be formed on the topmost nanolayer of the top transistor nanolayers 302. The mask layer may be comprised of any suitable mask material(s). The mask layer may be patterned and used to perform the nanolayer row 402 patterning process. In the nanolayer row 402 patterning process, any suitable material removal process (e.g., reactive ion etching or RIE) may be used to remove portions of the alternating top transistor nanolayers 302 down to the level of the bonding layer(s) 200. Following the nanolayer row 402 patterning process, one or more nanolayer rows 402 are formed. Subsequently, the mask layer may be removed.

For clarity, as depicted, one or more of the nanolayer rows 402 may include a linear portion 420 and a displaced portion 430. The displaced portion 430 may be displaced or offset relative to the linear portion 420 by curved, as depicted, non-linear, or linear walls or geometry. The one or more of the nanolayer rows 402 may be offset relative to the bottom nanolayers rows 102. For example, an edge or wall 420 of the nanolayer rows 402 may be inset within an associated bottom nanolayers row 102 there below.

The linear portion 420 may be laterally offset relative to the bottom nanolayer rows 102 by a first dimension 422 and the displaced portion 430 may be laterally offset relative to the bottom nanolayer rows 102 by a second dimension 432 that is less than the first dimension 422. For example, as depicted in the Y1 cross-section, linear portion 420 of the top nanolayer row 402 may be laterally offset relative to the active nanolayers 108 formed from the bottom nanolayer row 102 by the first dimension 422. Similarly, as depicted in the Y2 cross-section, displaced portion 430 of the top nanolayer row 402 may be laterally offset relative to the active nanolayers 108 formed from the bottom nanolayer row 102 by the second dimension 432 which is smaller than the first dimension 420. The relative difference between the first dimension 422 and the second dimension 432 may be provided by the degree of offset or geometry of the displaced portion 430, in relation to the linear portion 420 of the top nanolayer row 402.

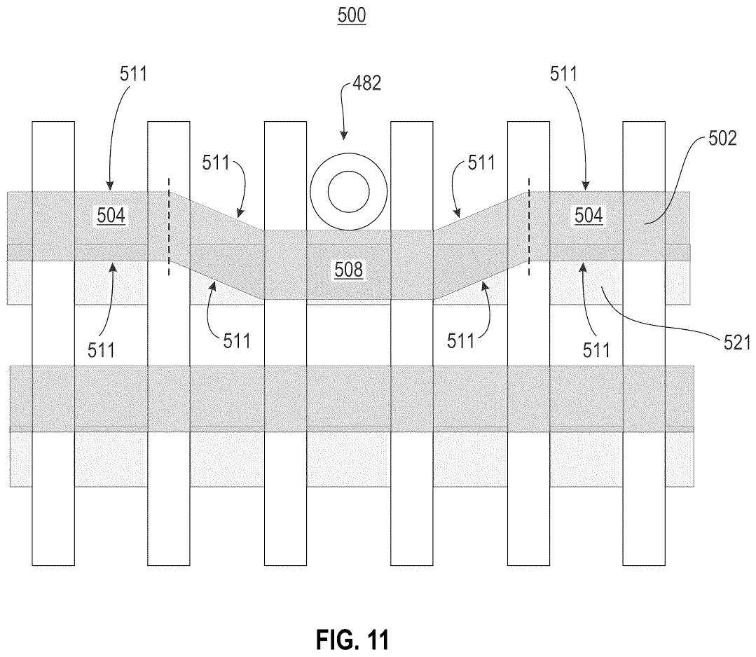

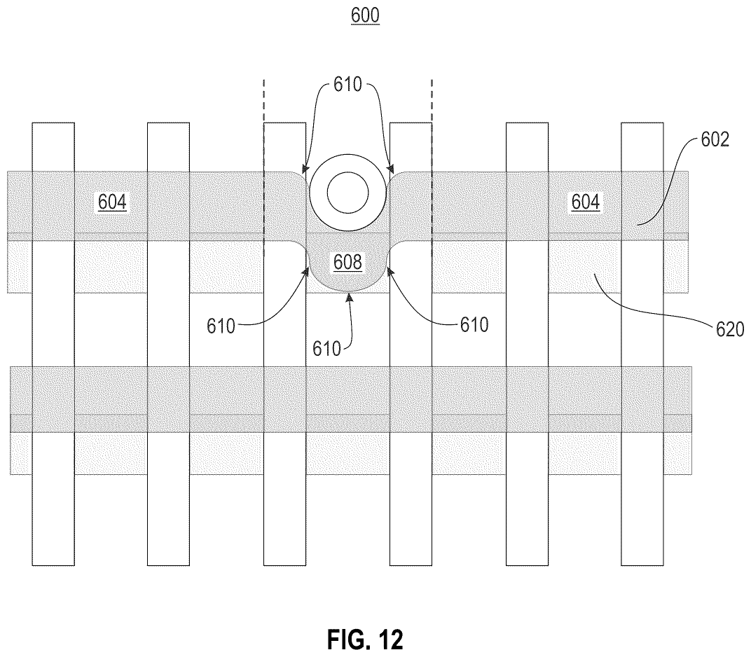

For clarity, in some embodiments, a Y dimension is substantially constant across the linear region 450 and the displaced portion 430 of top nanolayer row 402. In some embodiments, the displaced portion 430 is locally displaced between adjacent or neighboring gate structures, as depicted. In other embodiments, such as depicted in FIG. 11, the displaced portion 430 is locally displaced across multiple gate structures. In some embodiments, the displaced portion 430 has or is formed by substantially curved, arced, or non-linear walls, as depicted. In other embodiments, such as depicted in FIG. 12, the displaced portion 430 has or is formed by substantially linear walls.

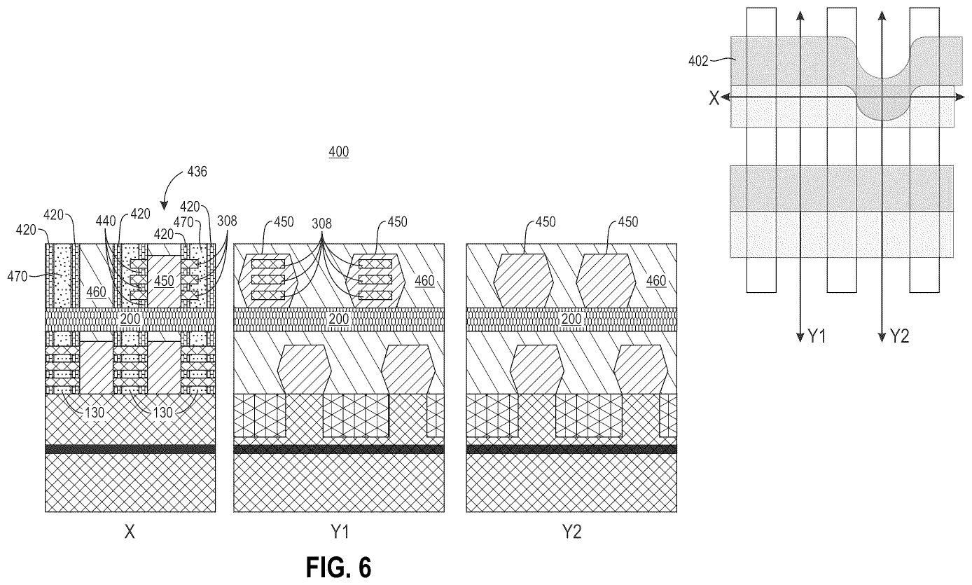

FIG. 6 depicts cross-sectional views of semiconductor IC device 400 shown after representative fabrication operation(s), in accordance with one or more embodiments. In the depicted stages, top sacrificial gate structures may be formed, top gate spacers 420 may be formed, top source/drain (S/D) canyons 436 may be formed, inner spacers 440 may be formed, top S/D regions 450 may be formed, top ILD 460 may be formed, and replacement gate structures 470 may be formed.

Semiconductor IC device 400 may be further formed by forming sacrificial gate structures (not shown) over the nanolayer rows 402. The one or more top sacrificial gate structures may include a top sacrificial gate liner (not shown), a top sacrificial gate (not shown), and a top sacrificial gate cap (not shown). The top sacrificial gate structures may be formed by initially depositing a top sacrificial gate liner layer (e.g., a dielectric, oxide, or the like) upon the bonding layer(s) 200 and upon and around the one or more nanolayer rows 402. The top sacrificial gate structures may further be formed by subsequently depositing a top sacrificial gate layer (e.g., amorphous silicon, or the like) upon the top sacrificial gate liner layer. The thickness of the top sacrificial gate layer may be such that the top surface of the top sacrificial gate layer is above the top surface of the one or more nanolayer rows 402. The top sacrificial gate structures may further be formed by forming a gate cap layer upon the top sacrificial gate layer. The gate cap layer may be formed by depositing a mask material, such as a hard mask material, such as silicon nitride, silicon oxide, combinations thereof, or the like, upon the top sacrificial gate layer. The gate cap layer may be composed of one or more layers of masking materials to protect the top sacrificial gate layer and/or other underlying materials during subsequent processing of semiconductor IC device 400.

The one or more top sacrificial gate structures may further be formed by patterning the gate cap layer, top sacrificial gate layer, and top sacrificial gate liner by, for example, using lithography and etch processes to remove undesired portions and retain desired portion(s), respectively. The retained portion(s) of the gate cap layer, top sacrificial gate layer, and top sacrificial gate liner may form the top sacrificial gate liner (not shown), the top sacrificial gate (not shown), and the top sacrificial gate cap (not shown), respectively, of each of the one or more top sacrificial gate structures.

One or more top sacrificial gate structures can be formed on targeted regions or areas of semiconductor IC device 400 to define the gate length of one or more top transistors and to provide sacrificial material for yielding targeted top transistor structure(s) in subsequent processing. In embodiments, a respective top sacrificial gate structure may be formed in line with a particular lower sacrificial gate structure. For clarity, the top sacrificial gate structures may be formed in line with a bottom replacement gate structure 130.

Further in the depicted fabrication stages, top gate spacers 420 may be formed. The top gate spacers 420 may be formed upon the sidewall(s) of the top sacrificial gate structures, upon the bonding layer(s) 200, and around the one or more nanolayer rows 402. The top gate spacers 420 may be formed by a conformal deposition of a dielectric material, such as silicon nitride, SiBCN, SiNC, SiN, SiCO, SiNOC, or a combination thereof, or the like, upon bonding layer(s) 200, upon and around the one or more top sacrificial gate structures, and upon and around the one or more nanolayer rows 402. Subsequently, undesired portions of dielectric material may be removed while desired portions the dielectric material may be retained and thereby form the top gate spacer(s). The undesired portions of dielectric material may be removed by a directional ion etch, such as a reactive ion etch (RIE).

Further in the depicted fabrication stages, top source/drain (S/D) canyons 436 may be formed within the one or more nanolayer rows 402 between top gate spacers 420 of neighboring top sacrificial gate structures. In other words, a single nanolayer row 402 may be separated, by a top S/D recess, into multiple nanolayer stacks, each located underneath a respective top sacrificial gate structure. The one or more top S/D canyons 436 may be formed between adjacent top sacrificial gate structures by removing respective portions of the top transistor nanolayers, that are between top gate spacers of adjacent or neighboring top sacrificial gate structures. The one or more top S/D canyons 436 may be formed to a depth to stop at the top surface of the bonding layer(s) 200, or the like.

The undesired portions of top transistor nanolayers may be removed by etching or other subtractive removal techniques. The top surface of the bonding layer(s) 200 may be used as an etch stop or other etch parameters may be controlled to stop the material removal at the bonding layer(s) 200. As the top gate spacers 420 and the top sacrificial gate structures may be utilized to protect the underlying portions of top transistor nanolayers, respective sidewalls of the nanolayer stacks may be substantially coplanar and/or substantially vertical with the outer sidewalls of the top gate spacers 420, there above.

Further in the depicted fabrication stages, sacrificial nanolayers may be indented and a respective top inner spacer 440 may be formed in each indent. For example, horizontal or lateral indents may be formed by laterally or horizontally (e.g., into and/or out of the page of the depicted Y1 cross-section) removing respective portions of sacrificial nanolayers within the nanolayer stacks. The indents may be formed by a reactive ion etch (RIE) process, which can remove portions of the sacrificial nanolayers. The horizontal depth of the indents may be chosen to set a length for a replacement gate structure that is formed in place of one top sacrificial gate structure. When the sacrificial nanolayers are composed of SiGe and when active nanolayers 308 are Si, the directional RIE can use a boron-based chemistry or a chlorine-based chemistry, for example, which recesses or removes the exposed end portions of sacrificial nanolayers (e.g., end portions of sacrificial nanolayers generally below the gate spacer) selective to the Si active nanolayers 308. In alternative implementations when sacrificial nanolayers are not SiGe and when active nanolayers 308 are not Si, the directional etch of the sacrificial nanolayers may generally be selective to the active nanolayers 308, top gate spacers 420, and/or bonding layer(s) 200.

Further in the depicted fabrication stages, a respective top inner spacer 440 may be formed within each indent. The one or more top inner spacers 440 can be formed by ALD or CVD or any other suitable deposition technique that deposits a dielectric material within the indent(s), thereby forming the top inner spacer(s). In some examples, the top inner spacers 440 are composed of a low-κ dielectric material, SiN, SiO, SiBCN, SiOCN, SiCO, etc. or any other suitable dielectric material. In certain implementations, after the formation of the top inner spacer 440, an isotropic etch process is performed to create substantially vertical sidewalls of the top inner spacer 440 that are coplanar with the substantially vertical sidewalls of the active nanolayers 308, of the top gate spacers 420, or the like.

A top S/D region 450 may be formed within each S/D canyon 436. The top S/D region 450 forms either a source or a drain, respectively, of respective top transistor, such as a GAA FET, and is connected to respective a side or end surface of the active nanolayers 308 of adjacent top nanolayer stacks. The top S/D region 450 may be composed of a semiconductor material and a dopant. The semiconductor material that provides each top S/D region 450 may be composed of one of the semiconductor materials mentioned above for the semiconductor structure. The semiconductor material that provides the top S/D region 450 can be compositionally the same, or compositionally different from each active nanolayers 308. The dopant that is present in the top S/D region 450 can be either a p-type dopant or an n-type dopant.

The one or more top S/D regions 450 may be epitaxially grown or formed from the exposed end surfaces of the active nanolayers 308), while epitaxial growth is limited or does not occur from bonding layer(s) 200. In some examples, the top S/D regions 450 may be formed by in-situ doped epitaxial growth. The use of an in-situ doping process is merely an example. For instance, one may instead employ an ex-situ process to introduce dopants into the source and drains. Other doping techniques can be used to incorporate dopants in the top source/drain region 450. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In examples, the S/D epitaxial growth conditions that promote in-situ Boron doped SiGe for p-type transistor and phosphorus or arsenic doped silicon or Si:C for n-type transistors.

In some embodiments, epitaxial growth to form the one or more top S/D regions 450 may overgrow above the top surface of the top sacrificial gate structure(s) and be subsequently recessed such that the top surface of the top S/D region 450 may be substantially horizontal and above the top surface of the topmost active nanolayer 308 within the nanolayer stacks (e.g., to enable contact between this active nanolayer 308 and the top S/D region 450).

Further in the depicted fabrication stages, a top interlayer dielectric (ILD) 460 may be formed. For example, a blanket top ILD 460 material may be deposited over the top S/D region(s) 420, upon the bonding layer(s) 200, over the top sacrificial gate structures, and over the top gate spacers 420 associated with adjacent top sacrificial gate structures.

The top ILD 460 can be any suitable material, such as, for example, porous silicates, carbon doped oxides, silicon dioxides, silicon nitrides, silicon oxynitrides, OPL, or other dielectric materials. Any known manner of forming the top ILD 460 can be utilized. The top ILD 460 can be formed using, for example, CVD, PECVD, ALD, flowable CVD, spin-on dielectrics, or PVD.

In an example, the top ILD 460 may be formed to a thickness above the top surface of the top sacrificial gate structures. Subsequently, a planarization process, such as a CMP, may be performed to remove excess top ILD 460 material and to remove the top sacrificial gate caps of the top sacrificial gate structures, thereby exposing the top sacrificial gate thereunder. The planarization may also partially remove some of the top sacrificial gates or may at least expose the top sacrificial gate of the top sacrificial gate structures. The CMP may create a substantially planar or substantially horizontal top surface for the semiconductor IC device 400. In other words, the respective top surfaces of the top ILD 460, top gate spacers 420, top sacrificial gates, etc. may be substantially coplanar and/or substantially horizontal.

Further, in the depicted fabrication stage(s), the top sacrificial gate structures and the lower sacrificial gate structures may be removed which may form a replacement gate structure opening. The top sacrificial gate structures and the lower sacrificial gate structures may be removed by a selective etch of the top gate and bottom gate material through the one or more replacement gate opening(s). In a particular embodiment, the removal of the sacrificial gate structures may further remove the sacrificial nanolayers 306. Therefore, void spaces may exist between the retained active nanolayers 308. Therefore, the active nanolayers 308 may be referred to as released. It should be appreciated that during the removal of the sacrificial gate structures appropriate etchants are used that do not significantly remove material of active nanolayers 308, bonding layer(s) 200, top gate spacers 420, top inner spacers 440, or the like.

Further, at the present stages of fabrication, replacement gate structures 470 are formed in place of the removed lower sacrificial gate structures around one or more active nanolayers 308. For clarity, the replacement gate structure 470 may be a distinct gate structure relative to the bottom gate replacement structure 130. In an example, the top replacement gate structure 470 may be inline with the bottom replacement gate structure 130.

A replacement gate structure 470 may be formed by initially forming an interfacial layer (not shown) on the interior surfaces of the replacement gate opening. Then, a high-κ layer (not shown) may be formed to cover the surfaces of exposed surfaces of the interfacial layer. The high-κ layer can be deposited by any suitable techniques, such as ALD, CVD, metal-organic CVD (MOCVD), physical vapor deposition (PVD), thermal oxidation, combinations thereof, or other suitable techniques. A high-κ dielectric material is a material with a higher dielectric constant than that of SiO₂, and can include e.g., LaO, AlO, ZrO, TiO, Ta₂O₅, Y₂O₃, SrTiO₃(STO), BaTiO₃ (BTO), BaZrO, HfZrO, HfLaO, HfSiO, LaSiO, AlSiO, HfTaO, HfTiO, (Ba, Sr)TiO₃ (BST), Al₂O₃, Si₃N₄, oxynitrides (SiON), or other suitable materials.

The replacement gate structure may be further formed by depositing a work function metal (WFM) gate upon the high-κ layer. The replacement gate can be comprised of metals, such as, e.g., copper (Cu), cobalt (Co), aluminum (Al), platinum (Pt), gold (Au), tungsten (W), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In various exemplary embodiments, the height of the replacement gate can be reduced by chemical-mechanical polishing (CMP) and/or etching. Therefore, the planarization process can be provided by CMP. Other planarization process can include grinding and polishing. In general, the replacement gate sets the threshold voltage (Vt) of the top transistors and the bottom transistors. The high-κ layer may separate the replacement gate from the active nanolayers 308 and the active nanolayers 108. Other metals that may be desired to further fine tune the effective work function (eWF) and/or to achieve a desired resistance value associated with current flow through the replacement gate structure.

Next, a metal fill may be formed over the WFM gate. The metal layer may include, e.g., Ti, Ag, Al, TiAlN, TaC, TaCN, TaSiN, Mn, Zr, TiN, TaN, Ru, Mo, Al, WN, Cu, W, or any suitable materials. After the replacement gate structure 470 formation, the top surface of the semiconductor IC device 400 may be planarized by a planarization technique such as a CMP, mechanical grinding process, or the like.

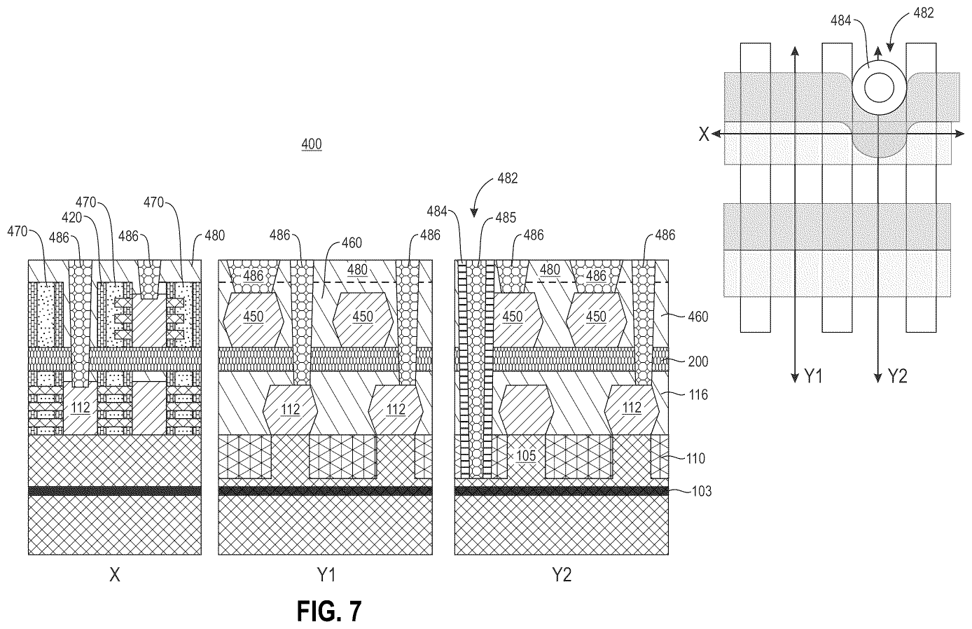

FIG. 7 depicts cross-sectional views of the semiconductor IC device 400 after fabrication operations, in accordance with embodiments of the present disclosure. In the depicted fabrication stages, frontside ILD 480 may be formed, a through interconnect 482 may be formed, one or more frontside contacts 486 may be formed.

The frontside contact frontside ILD 480 may be formed upon respective top surfaces of replacement gate structure(s) 470, ILD 460, and gate spacers 420. The frontside contact ILD 480 may be formed by depositing a dielectric material, such as, for example, porous silicates, carbon doped oxides, silicon dioxides, silicon nitrides, silicon oxynitrides, or other dielectric materials. The material of the frontside contact frontside ILD 480 may be the same as the material of the ILD 460, as depicted. Alternatively, the frontside contact frontside ILD 480 may be a relatively different dielectric material than the dielectric material of ILD 460.

Through interconnect 482 may be formed by forming an associated deep contact well through the ILD 480, ILD 460, upper S/D region 450, bonding layer(s) 200, ILD 116, and STI region 110 front the frontside of the semiconductor IC device 400 (i.e., from above the semiconductor IC device 400, as depicted, downward to respective structures thereof). The deep contact well may stop at the upper substrate 105, etch stop layer 103, or the like. The deep contact well may be formed by depositing a mask material, such as a hard mask material, such as silicon nitride, silicon oxide, combinations thereof, or the like, upon the frontside contact frontside ILD 480 and patterning the mask. A substrative removal technique, such as a deep via trench process, may form the deep contact well while the remaining mask may protect the underlying portions of the semiconductor IC device 400.

Through interconnect 482 may be further formed by forming a perimeter spacer 484 may be formed upon the sidewall(s) of the deep contact well. The perimeter spacer 484 may be formed by a conformal deposition of a dielectric material, such as silicon nitride, SiBCN, SiNC, SiN, SiCO, SiNOC, or a combination thereof, or the like. Subsequently, undesired portions of dielectric material may be removed while desired portions the dielectric material may be retained and thereby form the perimeter spacer 484. The undesired portions of dielectric material may be removed by a directional ion etch, such as a reactive ion etch (RIE). The through interconnect 482 may be further formed by depositing conductive material, such as a metal, into the respective the deep contact well upon the perimeter spacer 484 to form a conductive fill 485.

The frontside contacts 486 may be formed by patterning respective frontside contact openings (e.g., in the prior, same, or subsequent masking stage) within the frontside ILD 460, the frontside contact frontside ILD 480, bonding layer(s) 200, ILD 116, as appropriate, from the frontside of the semiconductor IC device.

Each frontside contacts 486 may be in direct or indirect physical and electrical contact with a respective region of the semiconductor IC device 400. For example, a particular frontside contact 486 may be directly connected to a bottom S/D region 112, a particular frontside contact 486 may be directly connected to a top S/D region 450, a particular frontside contact 486 may be directly connected to a replacement gate structure 470 (not shown), a particular frontside contact 486 may be directly connected to a replacement gate structure 470 (not shown), a particular frontside contact 486 may be directly connected to a replacement gate structure 130 (not shown), or the like.

The frontside contacts 486 may be formed by depositing conductive material such as metal into the respective frontside contact opening(s). In an example, frontside contacts 486 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, the conductive fill, and the through interconnect 482.

In embodiments, the frontside contacts 486 and the through interconnect 482 are fabricated in middle-of-line (MOL) fabrication operations and may be illustrations of MOL contacts. For clarity, the frontside contacts 486 and the through interconnect 482 may be formed in sequential (e.g., the frontside contacts 486 are formed and the through interconnects 482 are then formed, or vice versa) or simultaneous MOL fabrication operations.

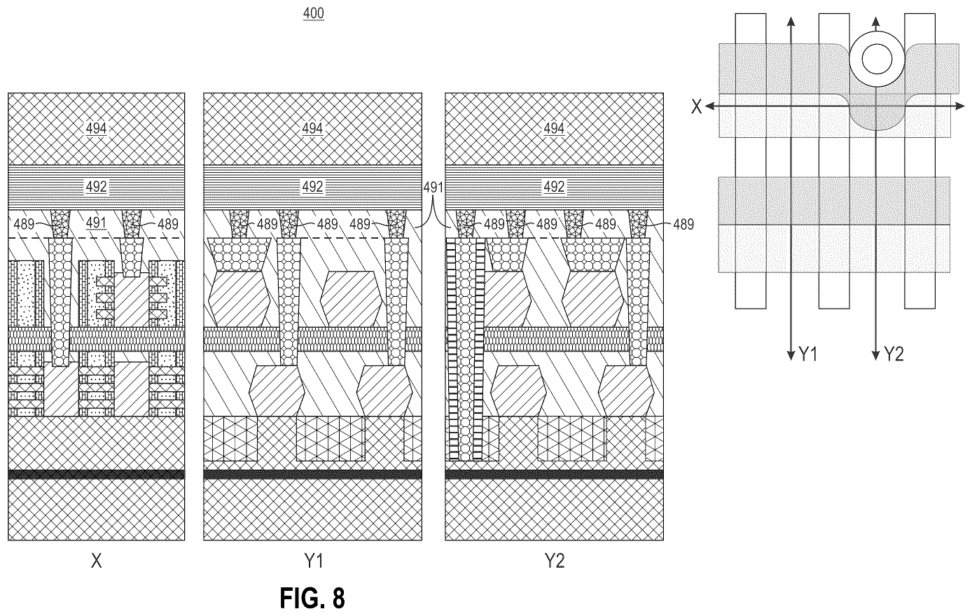

FIG. 8 depicts cross-sectional views of the semiconductor IC device 400 after fabrication operations, in accordance with embodiments of the present disclosure. In the depicted fabrication stages, a frontside back end of the line (BEOL) network 492 may be formed, and a carrier wafer 494 may be bonded thereto.

A frontside BEOL network 492 may be formed and a carrier wafer 494 may be bonded to the frontside BEOL network 492. The frontside BEOL network 492 may be connected to the frontside contacts 486 and the through interconnect 482 by a respective conductive contact via 489 that is formed in an ILD 491. The contact via 489 and the ILD 491 may be formed by fabrication techniques that are described herein and are not repeated.

In the semiconductor IC device fabrication industry, there are three sections referred to in a build: front-end-of-line (FEOL), BEOL, and the section that connects those two together, the MOL. The FEOL is made up of devices, e.g., transistors, the BEOL is made up of interconnects and wiring, and the MOL includes interconnects between the FEOL and BEOL and material to prevent the diffusion of BEOL conductive material(s) to the FEOL devices.

The BEOL section is the portion of IC fabrication where the individual devices (e.g., transistors, capacitors, resistors, etc.) become interconnected with wiring on the semiconductor IC device, e.g., the metallization layer or layers of a wafer. The BEOL section includes contacts, insulating layers (dielectrics), metal levels, and bonding sites for chip-to-package connections. In the BEOL section, part of the fabrication stage contacts (pads), interconnect wires, vias and dielectric structures are formed. For modern IC processes, more than one metal layers may be added in the BEOL section.

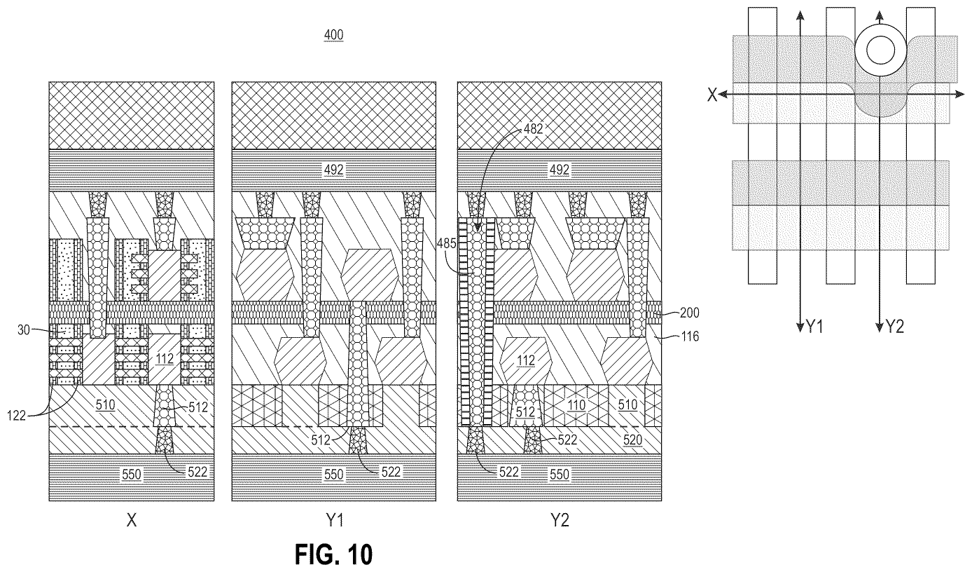

In the present example, there are multiple BEOL levels each on opposites sides of the semiconductor IC device 400. First, a frontside BEOL network 492 is formed on the frontside of the semiconductor device 400. Subsequently, a backside BEOL network 550, as depicted in FIG. 10, may be formed.

In the depicted example, the frontside BEOL network 492 is formed over the frontside contacts 486 and the through interconnect 482. Respective wires within the frontside BEOL network 492 may be electrically connected to the frontside contacts 486, the through interconnect 482, etc. The frontside BEOL network 492 can include one or more interconnect dielectric material layers (including one of the dielectric materials mentioned above for the frontside ILD 480) and contains conductive wires (the conductive wires can be composed of any electrically conductive material, metal, electrically conductive metal alloy, or the like) embedded therein. In some embodiments, the frontside conductive wires within the frontside BEOL network 492 are composed of Cu. The frontside BEOL network 492 can include “x” numbers of frontside metal levels, wherein “x” is an integer starting from 1. The frontside BEOL network 492 may further contain conductive pads that are connected to one or more of the conductive wires and may be used to connect the semiconductor IC device 100 to an external and/or higher-level structure, such as a chip carrier, motherboard, or the like.

The illustrated semiconductor IC device 400 may be further fabricated by bonding carrier wafer 494 to the frontside BEOL network 492. The carrier wafer 494 can include one of the semiconductor materials mentioned above for the semiconductor structure and the carrier wafer may be attached to the semiconductor IC device 400 by a wafer-to-wafer bonding technique.

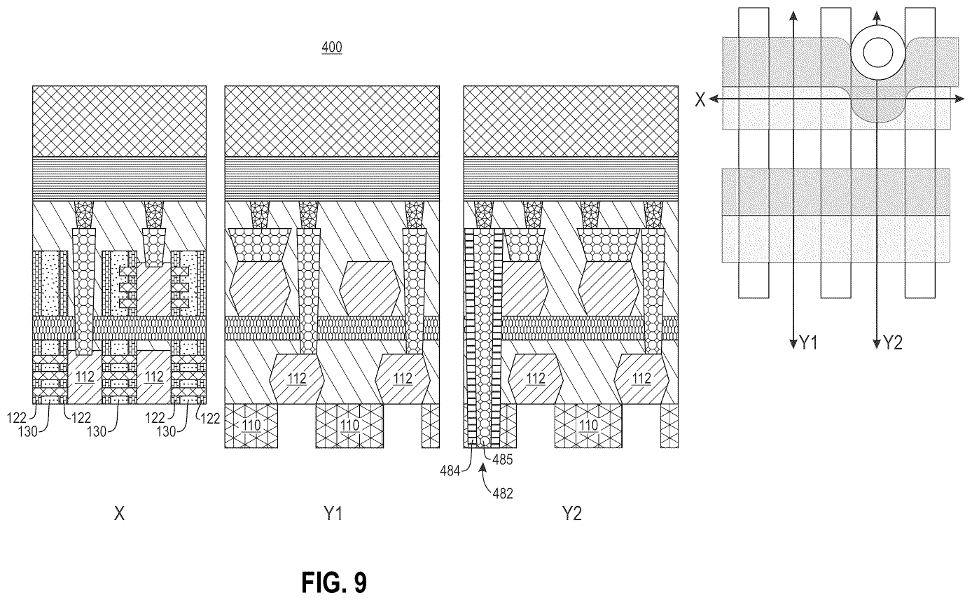

FIG. 9 depicts cross-sectional views of the semiconductor IC device 100 after fabrication operations, in accordance with embodiments of the present disclosure. In the depicted fabrication stages, lower substrate 101, etch stop layer 103, and upper substrate 105 may be removed.

The lower substrate 101 may be removed may be recessed by flipping the semiconductor IC device 400 and removing lower substrate 101 by appropriate substrative removal techniques, such as one or more series of etches. The one or more etches may be timed or otherwise controlled to remove the material of lower substrate 101 selective to the STI regions 110 and may utilize the etch stop layer 103 as an etch stop.

The etch stop layer 103 may be removed by appropriate substrative removal techniques, such as one or more series of etches. The one or more etches may be timed or otherwise controlled to remove the material etch stop layer 103 selective to the STI regions 110 and may utilize the upper substrate 105 as an etch stop.

The upper substrate 105 may be removed by appropriate substrative removal techniques, such as one or more series of etches. The one or more etches may be timed or otherwise controlled to remove the material upper substrate 105 selective to the STI regions 110, the replacement gate structures 130, the bottom most inner spacers 122, and the bottom S/D regions 112, or the like.

The etch that removes the upper substrate 105 may further partially etch or gouge those S/D regions 112 that do not have adequate etch selectivity with respect thereto. For example, when the upper substrate 105 is composed of Si, the etch to remove the upper substrate 105 may further partially etch or gouge those S/D regions 112 that are also composed of Si. The partial etch or gouging of these S/D regions 112 may form a gouge within the S/D regions 112 (not shown).

FIG. 10 depicts cross-sectional views of the semiconductor IC device 100 after fabrication operations, in accordance with embodiments of the present disclosure. In the depicted fabrication stages, a backside ILD 510 may be formed, backside contacts 512 may be formed, a backside via ILD 520 may be formed, a backside via 522 may be formed, and a backside BEOL network 550 may be formed.

The backside ILD 510 may be formed upon the backside of the semiconductor IC device 400 (i.e., as depicted from below the semiconductor IC device 400 upward). The backside ILD 510 may be formed directly upon the backside of the replacement gate structures 130, upon the STI regions 110, and upon the backside of the bottom S/D regions 112. The backside ILD 510 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 510 can be utilized. The backside ILD 510 can be formed using, for example, CVD, PECVD, ALD, flowable CVD, spin-on dielectrics, or PVD.

In an example, as depicted, the material of the backside ILD 510 may be the same material as the ILD 460. In alternative examples, the material of the backside ILD 510 may be chosen to achieve a predetermined electrical isolation metric that the dielectric material of ILD 460 could not achieve, if utilized. For example, ILD 460 may be silicon dioxide and the backside ILD 510 may be a low-κ dielectric material.

Subsequently, a planarization process, such as a CMP, may planarize the bottom surface of the backside ILD 510 and a bottom surface of the STI regions 110 and a bottom surface of the through interconnect 482. As a result, the respective bottom surfaces of the STI regions 110, the backside ILD 510, and the through interconnect 482 may be substantially horizontal and/or substantially coplanar.

The one or more backside contacts 512 may be formed by initially forming associated backside contact openings by lithography and etch process(es). In such process(es), a mask (not shown) may be applied to the backside of the semiconductor IC device 400 and patterned. Openings in the patterned mask may sequentially expose the portion(s) of the underlying backside ILD 510 that are to be removed while other protected portions of semiconductor IC device 100 may be protected and retained.

A backside contact opening may be located with respect to an associated bottom S/D region 112 or and associated top S/D region 450. The backside contact opening may be formed to expose the associated S/D region 112 there above by removing the associated portion of the backside ILD 510. The backside contact opening may be formed to expose the associated S/D region 450 there above by removing the associated portion of the STI region 110, ILD 116, and bonding layer(s) 200. For clarity, the backside contacts 512 that connect to the bottom S/D regions 112 may be formed in prior, same, or subsequent operations relative to the backside contacts 512 that connect to the top S/D regions 450.

The backside contacts 512 may be further formed by forming a particular backside contact 512 within a respective backside contact opening against the associated S/D region 112 or the associated S/D region 450. The backside contacts 512 may be formed by depositing conductive material, such as metal, within the backside contact openings. In an example, multiple backside contacts 512 may be simultaneously formed by depositing a liner, such as Ni, NiPt or Ti, etc. onto the backside of semiconductor IC device 400 and into the backside contact openings, depositing an adhesion liner, such as TiN, TaN, etc. upon the liner, and by depositing a conductive fill, such as Al, Ru, W, Co, Cu, etc. upon the adhesion liner. Subsequently, a planarization process, such as a CMP, may expose a bottom surface of the backside ILD 510, the respective bottom surfaces of the backside contacts 512, and the respective bottom surface of the STI regions 110. As a result, the respective bottom surfaces of backside contacts 512, the STI regions 110, and the backside ILD 510 may be substantially horizontal and/or substantially coplanar.

The BEOL network 550 may be formed may be connected to the backside contacts 512 and the through interconnect 482 by a respective conductive backside contact via 522 that is formed in a backside ILD 520. The backside contact via 522 and the backside ILD 520 may be formed by fabrication techniques that are described herein and are not repeated.

The backside BEOL network 550, such as a backside power distribution network (BSPDN) may be formed upon the backside contact vias 522, etc. The backside BEOL network 550 may include signal wires for signal routing and power wires for providing power potential (e.g., VDD, VSS, etc.). The backside BEOL network 550 may allow for the distribution of power wires and signal wires between both the frontside and backside of the semiconductor IC device. The backside BEOL network 550 may further allow for the full or partial decoupling of signal routing and/or power routing and/or allows for dividing or splitting power wires and/or signal wires between both the frontside BEOL network 492 and the backside BEOL network 550 of the semiconductor IC device 400. By also incorporating the backside BEOL network 550, wire and contact routing congestion may be reduced, which may lead to further semiconductor IC device 100 scaling. For example, semiconductor IC devices that incorporate a backside BEOL network can result in a 30% area reduction and improved current-resistance (IR) drop compared to typical semiconductor IC devices that include solely a frontside BEOL network.

The backside BEOL network 550 can include one or more interconnect dielectric material layers and contains backside conductive wires and/or interconnects, such as VIAs, embedded therein. In some embodiments, the backside wires within the backside BEOL network 550 are composed of Cu. The backside BEOL network 550 can include “x” numbers of backside metal levels, wherein “x” is an integer starting from 1. If not included in frontside BEOL network 492, backside BEOL network 550 may further contain conductive pads that are connected to one or more of the backside metal wires and may be used to connect the semiconductor IC device 100 to the external and/or higher-level structure.

In an example, signal routing and power routing is effectively split between the frontside BEOL network 492 and the backside BEOL network 550. For example, at least 90% of the frontside metal wires (e.g., furthest from the depicted transistors) are signal routing metal wires and the remainder frontside metal wires which are usually present in metal levels closest to the transistors, can be used as power routing wires. Further in this example, at least 90% of the backside metal wires that are in metal levels closest to the backside contacts are power routing metal wires. Power routing wires may be less dense than signal routing wires. A signal routing wire is defined herein as a conductive feature, such as a wire, interconnect, or the like, that is configured to carry or have a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like. For clarity, at least the conductive fill 485 of the through interconnect 482 is connected to both the frontside BEOL network 492 and to the backside BEOL network 550.

Semiconductor IC device 400 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

FIG. 11 depicts a partial top down view of an illustrative semiconductor IC device 600 that includes a locally displaced top transistor active area 602, according to one or more embodiments of the disclosure. The top transistor active area 602 includes a first portion 604 that is laterally offset relative to a bottom active region 620 by a first dimension and a locally displaced portion 608 that is laterally offset relative to the bottom active region 620 by a second dimension that is less than the first dimension. In the illustrative embodiment, the locally displaced portion 608 spans more than the two neighboring gate structures (e.g., replacement gate structures 470, or the like) and includes substantially linear sidewalls 511. In examples, the through interconnect 482 may directly contact the locally displaced portion 608 of the locally displaced top transistor active area 602. For clarity, in a similar embodiment, the locally displaced portion 608 that spans more than the two neighboring gate structures could have curved or other non-linear sidewalls, similar to those depicted in the other embodiments.

FIG. 12 depicts a partial top down view of an illustrative semiconductor IC device 500 that includes a locally displaced top transistor active area 502, according to one or more embodiments of the disclosure. The top transistor active area 502 includes a first portion 504 that is laterally offset relative to a bottom active region 521 by a first dimension and a locally displaced portion 508 that is laterally offset relative to the bottom active region 521 by a second dimension that is less than the first dimension. In the illustrative embodiment, the locally displaced portion 508 between adjacent gate structures (e.g., replacement gate structures 470, or the like) and includes non-linear or curved (e.g., S-curved, or the like) sidewalls 610. In examples, the through interconnect 482 may directly contact the locally displaced portion 508 of the locally displaced top transistor active area 502. For clarity, in a similar embodiment, the locally displaced portion 508 between adjacent gate structures could have linear sidewalls, similar to those depicted in the other embodiments.

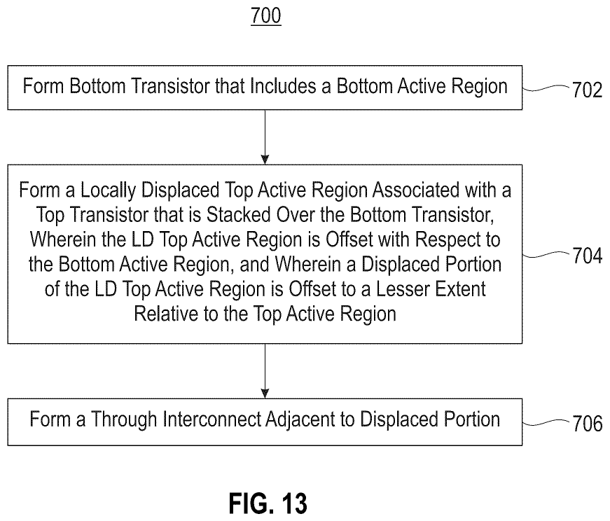

FIG. 13 depicts a flow diagram illustrating a method 700 to fabricate a semiconductor IC device. The depicted fabrication operations of method 700 may be illustratively depicted and described above with reference to one or more of FIG. 2 through FIG. 10 of the drawings, which describe the fabrication of a semiconductor IC device at various stages of fabrication, though various fabrication operations described in method 700 may be used to fabricate other types of semiconductor IC devices. The method 700 depicted herein is illustrative. There can be many variations to the diagram or operations described therein without departing from the spirit of the embodiments. For instance, the operations can be performed in a differing order, or operations can be added, deleted, or modified.

Method 700 may begin, at block 702, with forming a bottom transistor that includes a bottom active region. For example, semiconductor IC device 100 may be formed.

Method 700 may continue, at block 704, with forming a locally displaced top active region that is associated with a top transistor that is stacked over the bottom transistor. The locally displaced top active region is offset or shifted with respect to the bottom active region and includes a displaced portion or region thereof that is offset or shifted to a lesser extent. For example, the top transistor active area may include a first portion that is laterally offset relative to the bottom active region by a first dimension and a locally displaced portion that is laterally offset relative to the bottom active region by a second dimension that is less than the first dimension.

Method 700 may continue, at block 706, with forming a through interconnect adjacent, in indirect contact with, or in direct contact with the displaced portion or region thereof that is offset or shifted to a lesser extent. In other words, the local displacement of the displaced portion may allow adequate space for placement of the through interconnect without otherwise increasing a horizontal cell dimension to provide for this adequate space.

The semiconductor IC devices described herein may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a bottom active region; and
a top active region comprising:
a first portion that is laterally offset relative to the bottom active region by a first dimension; and
a locally displaced portion that is laterally offset relative to the bottom active region by a second dimension less than the first dimension.

2. The semiconductor IC device of claim 1, further comprising:
a through interconnect adjacent to the locally displaced portion.

3. The semiconductor IC device of claim 2, wherein the through interconnect comprises a perimeter dielectric liner and an internal conductive pillar.

4. The semiconductor IC device of claim 3, a top source/drain (S/D) region within the locally displaced portion of the top active region.

5. The semiconductor IC device of claim 4, wherein the top S/D region is connected to a frontside back end of line (BEOL) network.

6. The semiconductor IC device of claim 5, wherein the top S/D region is directly connected to the perimeter dielectric liner of the through interconnect.

7. The semiconductor IC device of claim 6, a bottom S/D region within the bottom active region below the top S/D region.

8. The semiconductor IC device of claim 7, wherein the bottom S/D region is connected to a backside BEOL network.

9. The semiconductor IC device of claim 8, wherein the internal conductive pillar is connected to the frontside BEOL network and to the backside BEOL network.

10. A semiconductor integrated circuit (IC) device comprising:
a first cell that has a horizontal cell height dimension, the first cell comprising a first dimension from an edge of a top active region to a distal edge of a bottom active region; and
a second cell that has the horizontal cell height dimension, the second cell comprising a second dimension from the edge of the top active region to the distal edge of the bottom active region, wherein the second dimension is less than the first dimension.

11. The semiconductor IC device of claim 10, wherein the top active region comprises a first portion in the first cell and a locally displaced portion within the second cell.

12. The semiconductor IC device of claim 11, wherein the locally displaced portion of the top active region is curved relative to the first portion of the top active region.

13. The semiconductor IC device of claim 11, further comprising:
a through interconnect adjacent to the locally displaced portion.

14. The semiconductor IC device of claim 13, wherein the through interconnect comprises a perimeter dielectric liner and an internal conductive pillar.

15. The semiconductor IC device of claim 14, a top source/drain (S/D) region within the locally displaced portion of the top active region.

16. The semiconductor IC device of claim 15, wherein the top S/D region is connected to a frontside back end of line (BEOL) network.

17. The semiconductor IC device of claim 16, wherein the top S/D region is directly connected to the perimeter dielectric liner of the through interconnect.

18. The semiconductor IC device of claim 17, a bottom S/D region within the bottom active region.

19. The semiconductor IC device of claim 18, wherein the bottom S/D region is connected to a backside BEOL network.

20. A semiconductor integrated circuit (IC) device fabrication method comprising:
forming a bottom transistor that includes a bottom active region; and
forming a locally displaced top active region that comprises a first portion that is laterally offset relative to the bottom active region by a first dimension and a locally displaced portion that is laterally offset relative to the bottom active region by a second dimension less than the first dimension.
